(19) United States
(12) Patent Application Publication
(10) Pub. No.: US 2024/0145268 A1
(43) Pub. Date: May 2, 2024

(54) MOLDING APPARATUS FOR FABRICATING SEMICONDUCTOR PACKAGE AND MOLDING METHOD OF SEMICONDUCTOR PACKAGE

(71) Applicant: Samsung Electronics Co., Ltd., Suwon-si (KR)

(72) Inventors: Jun Woo Park, Suwon-si (KR); Gyu Hyeong Kim, Suwon-si (KR); Seung Hwan Kim, Suwon-si (KR); Jung Joo Kim, Suwon-si (KR); Jong Wan Kim, Suwon-si (KR); Yong Kwan Lee, Suwon-si (KR)

(21) Appl. No.: 18/468,192

(22) Filed: Sep. 15, 2023

(30) Foreign Application Priority Data
Oct. 31, 2022 (KR) 10-2022-0142678
Nov. 23, 2022 (KR) 10-2022-0158474

(51) Int. Cl. H01L 21/67; H01L 21/56; H01L 21/68

(52) U.S. Cl. CPC H01L 21/67126; H01L 21/565; H01L 21/67017; H01L 21/68

(57) ABSTRACT

A molding apparatus for fabricating a semiconductor package includes an upper mold including an upper cavity, a first side cavity at a first side of the upper cavity, a second side cavity formed at an opposite second side of the upper cavity, and a first driving part connected to the first side cavity and configured to move the first side cavity in a first direction, and a bottom mold including a bottom cavity configured to receive a molding target including a package substrate and at least one semiconductor chip. A width in the first direction between the first side cavity and the second side cavity may be smaller than a width of the package substrate in the first direction and greater than a width in the first direction between a first boundary and a second boundary of the at least one semiconductor chip.

### CROSS-REFERENCE TO RELATED APPLICATION

This application claims priority under 35 U.S.C. 119 from Korean Patent Application No. 10-2022-0142678, filed on Oct. 31, 2022 and Korean Patent Application No. 10-2022-0158474, filed on Nov. 23, 2022 in the Korean Intellectual Property Office, the contents of which are herein incorporated by reference in their entirety.

### BACKGROUND

The present disclosure relates to a molding apparatus for fabricating a semiconductor package and a molding method of the semiconductor package.

Generally, a semiconductor package seals a semiconductor chip and an upper surface of a package substrate in which the semiconductor chip is packaged, through a molding process to protect the semiconductor chip from external impact. A body of the semiconductor package may be formed through such a molding process to protect the semiconductor chip inside the semiconductor package from external thermal and mechanical impact.

Meanwhile, with the development of the electronic industry, demands for high functionality, high-speed and miniaturization of electronic components have been increased. In response to this trend, various technologies for providing a semiconductor package of high capacity have been studied and developed. In this way, in order to provide a semiconductor package of high capacity, studies for stack package and multi-chip package technologies in which two to three semiconductor chips are mounted in one semiconductor package are actively ongoing.

However, when a plurality of semiconductor chips are mounted in one package as described above, upper and side margins of a molding member (or molding material) are reduced when a molding process of the semiconductor package is performed, so that the molding member does not flow smoothly, whereby defects such as non-filling of the molding member and a void trap may occur.

Accordingly, studies for a technology capable of preventing defects such as non-filling of the molding member and a void trap from occurring during a molding process for a semiconductor package on which a plurality of semiconductor chips are mounted are ongoing.

### SUMMARY

An object of the present disclosure is to provide a molding apparatus for fabricating a semiconductor package, which has improved reliability.

Another object of the present disclosure is to provide a molding method of a semiconductor package, which has improved reliability.

According to some aspects of the present disclosure, there is a provided a molding apparatus for fabricating a semiconductor package including an upper mold including an upper cavity, a first side cavity formed at a first side of the upper cavity, a second side cavity formed at an opposite second side of the upper cavity, and a first driving part connected to the first side cavity configured to move the first side cavity in a first direction, and a bottom mold including a bottom cavity configured to receive a molding target including a package substrate and at least one semiconductor chip, wherein a width in the first direction between the first side cavity and the second side cavity is smaller than a width of the package substrate in the first direction and greater than a width in the first direction between a first boundary and a second boundary of the at least one semiconductor chip.

According to some aspects of the present disclosure, there is a provided a molding method of the semiconductor package including: providing a molding apparatus for fabricating the semiconductor package, the molding apparatus including: an upper mold including an upper cavity, a first side cavity formed at a first side of the upper cavity, a second side cavity formed at am opposite second side of the upper cavity, a first driving part connected to the first side cavity and configured to move the first side cavity in a first direction, and a second driving part connected to the second side cavity and configured to move the second side cavity in the first direction, and a bottom mold including a bottom cavity configured to receive a molding target, setting a position of the first side cavity in the first direction by the first driving part, spacing the upper mold apart from the bottom mold by a first loader moving the upper mold in a second direction and/or a second loader moving the bottom mold in the second direction, placing the molding target on the bottom cavity by a third loader, clamping the upper mold and the bottom mold by the first loader and the second loader, supplying a molding material between the upper cavity, the first side cavity, and the second side cavity by a fourth loader, and separating the upper mold from the bottom mold by the first loader and/or the second loader, wherein the first driving part and the second driving part are operated by a wedge mechanism.

According to some aspects of the present disclosure, there is a provided molding method of a semiconductor package including: providing a molding apparatus for fabricating the semiconductor package, the molding apparatus including: an upper mold including an upper cavity, a first side cavity formed at a first side side of the upper cavity, a second side cavity formed at an opposite second side of the upper cavity and a first driving part connected to the upper cavity and configured to move the upper cavity in a first direction, and a bottom mold including a bottom cavity configured to receive a molding target, setting the upper cavity to a first position by the first driving part, spacing the upper mold apart from the bottom mold by a first loader moving the upper mold in the first direction and/or a second loader moving the bottom mold in the first direction, placing the molding target on the bottom cavity by a carrier, clamping the upper mold and the bottom mold by the first loader and/or the second loader so that there is no empty space between an uppermost end of the molding target and the upper cavity, supplying a molding material to inside of the upper cavity, the first side cavity and the second side cavity by a molding material supply unit, separating the upper mold from the bottom mold by the first loader and/or the second loader, setting the upper cavity to a second position lower than the first position in the first direction by the first driving part, clamping the upper mold and the bottom mold again by the first loader and the second loader, supplying the molding material to an uppermost end of the molding target by the molding material supply unit, and separating the upper mold from the bottom mold again by the first loader and/or the second loader.

The objects of the present disclosure are not limited to those mentioned above and additional objects of the present disclosure, which are not mentioned herein, will be clearly understood by those skilled in the art from the following description of the present disclosure.

### BRIEF DESCRIPTION OF DRAWINGS

The above and other aspects and features of the present disclosure will become more apparent by describing in detail example embodiments thereof with reference to the attached drawings, in which:

FIGS. 1 to 3 are example views illustrating a molding apparatus for fabricating a semiconductor package according to some embodiments.

FIG. 4 is a cross-sectional view taken along line I-I of FIG. 1.

FIG. 5 is an example diagram illustrating an effect of the molding apparatus for fabricating a semiconductor package in FIG. 1

FIG. 6 is an example view illustrating a structure in which an intaglio is formed inside an upper cavity, side cavities and a bottom cavity of the molding apparatus for fabricating the semiconductor package of FIG. 1.

FIG. 7 is an enlarged view illustrating portion II of FIG. 6.

FIG. 8 is a view illustrating a structure in which an upper mold and a bottom mold of FIG. 7 are clamped.

FIG. 9 is a flow chart illustrating a molding method of a semiconductor package according to some embodiments.

FIGS. 10 to 15 are views illustrating intermediate steps to describe a molding method of a semiconductor package according to some embodiments.

FIG. 16 is a flow chart illustrating a molding method of a semiconductor package according to some embodiments.

FIGS. 17 to 26 are views illustrating intermediate steps to describe a molding method of a semiconductor package according to some embodiments.

### DETAILED DESCRIPTION

Hereinafter, a molding apparatus of a semiconductor package and a molding method of the semiconductor package according to some embodiments will be described with reference to the accompanying drawings.

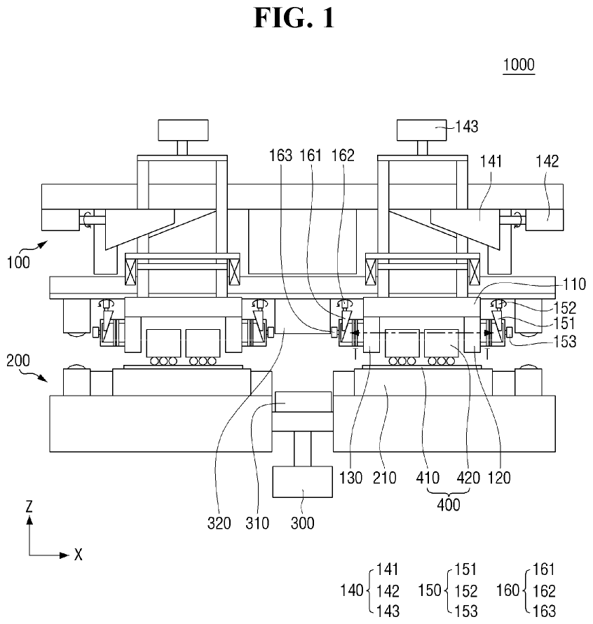

FIGS. 1 to 3 are example views illustrating a molding apparatus for fabricating a semiconductor package according to some embodiments.

Referring to FIG. 1, a molding apparatus 1000 for fabricating a semiconductor package according to some embodiments may include an upper mold 100, a bottom or lower mold 200 and a molding material supply unit or molding material supply system 300. The upper mold 100 may include an upper cavity 110, a first side cavity 120, a second side cavity 130, a first driving part 140, a second driving part 150 and a third driving part 160. The bottom mold 200 may include a bottom or lower cavity 210. As used herein, the terms “upper cavity,” “first side cavity,” “second side cavity,” and “bottom cavity” may refer to structural elements including structural features such as blocks and plates.

As shown in FIG. 1, the molding apparatus 1000 for fabricating a semiconductor package according to some embodiments may have a structure in which the upper cavity 110 is formed in the upper mold 100 and the first side cavity 120 and the second side cavity 130 are symmetrically formed in the upper cavity 110. Also, the molding apparatus 1000 for fabricating a semiconductor package may have a structure in which the bottom mold 200 is disposed below the upper mold 100 and the bottom cavity 210 is formed in the bottom mold 200.

In addition, the molding apparatus 1000 for fabricating a semiconductor package may have a symmetrical structure to mold two molding targets by a molding forming process of one time, but the present disclosure is not limited thereto. The molding apparatus for fabricating a semiconductor package according to some embodiments may have a structure other than the symmetrical structure.

Hereinafter, as shown in FIG. 1, the molding apparatus 1000 for fabricating a semiconductor package, which has a symmetrical structure, will be described as an example. Also, a structure shown at a right side of the molding apparatus 1000 for fabricating the semiconductor package shown in FIG. 1 will be described as an example. In this case, the description of the structure shown at the right side of FIG. 1 may be equally applied to a structure shown at a left side of FIG. 1.

The first driving part 140 may be connected to the upper cavity 110 to move the upper cavity 110 in a first direction Z. In some embodiments, the first driving part 140 may be operated by a wedge mechanism, but the present disclosure is not limited thereto. The first driving part 140 may be operated by all operation mechanisms suitable for moving the upper cavity 110 in the first direction Z.

In some embodiments, the first driving part 140 may include a first sliding block 141, a first motor 142 and a first cylinder 143. The first sliding block 141 may have an inclined surface for adjusting a position of the first cylinder 143 in the first direction Z. The first motor 142 may be connected to the first sliding block 141 to control the first sliding block 141 so that the first sliding block 141 may reciprocate in a second direction X.

The first cylinder 143 may move to one side (e.g., downward direction) of the first direction Z in accordance with forward movement (e.g., movement in a left direction) of the first sliding block 141 in the second direction X, which has received a power from the first motor 142. In addition, the first cylinder 143 may move to the other side (e.g., upward direction) of the first direction Z in accordance with backward movement (e.g., movement in a right direction) of the first sliding block 141 in the second direction X.

The first cylinder 143 may be connected to the upper cavity 110. Therefore, as the first cylinder 143 moves in the first direction Z, a position of the upper cavity 110 in the first direction Z may be changed. The position of the upper cavity 110 in the first direction Z may determine a height of a mold body in the first direction Z, which covers a molding target 400. For example, when the first sliding block 141 receives a large amount of power from the first motor 142, the first sliding block 141 may move forward (e.g., move in the left direction) in the second direction X with a large width or distance. Therefore, the first cylinder 143 may move to one side (e.g., downward direction) of the first direction Z with a large width or distance. In this way, when the first cylinder 143 moves downward in the first direction Z with a large width, the height of the mold body, which covers the molding target 400, in the first direction Z may be low.

Meanwhile, when the first sliding block 141 receives less power from the first motor 142, the first sliding block 141 may move forward (e.g., move in the left direction) in the second direction X with a relatively small width or distance. Therefore, the first cylinder 143 may move to one side (e.g., downward direction) of the first direction Z with a relatively small width or distance. In this way, when the first cylinder 143 moves downward to one side (e.g., downward direction) of the first direction Z with a small width, the height of the mold body, which covers the molding target 400, in the first direction Z may be relatively high.

As described above, in the molding apparatus 1000 for fabricating a semiconductor package according to some embodiments, the height of the upper cavity 110 in the first direction Z may be adjusted by the first driving part 140 operated by a wedge mechanism, so that the height of the mold body in the first direction Z, which covers the molding target 400, may be set in various ways.

The first side cavity 120 may be formed at one side of the upper cavity 110. The second side cavity 130 may be formed at the other (e.g., opposite) side of the upper cavity 110. That is, as shown in FIG. 1, in some embodiments, the first side cavity 120 and the second side cavity 130 may be disposed to face each other at one side and the other side, which are opposite to each other, of the upper cavity 110.

In some embodiments, the first side cavity 120 and the second side cavity 130 may move in the second direction X by the second driving part 150 and the third driving part 160, respectively. Hereinafter, the first side cavity 120, which moves in the second direction X by the second driving part 150, will be described by way of example, but the same operating principle may be applied to the second side cavity 130 which moves in the second direction X by the third driving part 160.

The second driving part 150 may be connected to the first side cavity 120 to move the first side cavity 120 in the second direction X. In some embodiments, the second driving part 150 may be operated by a wedge mechanism, but the present disclosure is not limited thereto. The second driving part 150 may be operated by all operation mechanisms suitable for moving the first side cavity 120 in the second direction X.

In some embodiments, the second driving part 150 may include a second sliding block 151, a second motor 152 and a second cylinder 153. The second sliding block 151 may have an inclined surface for adjusting a position of the second cylinder 153 in the second direction X. The second motor 152 may be connected to the second sliding block 151 to control the second sliding block 151 so that the second sliding block 151 may reciprocate in the first direction Z.

The second cylinder 153 may move to one side (e.g., left direction) of the second direction X in accordance with forward movement of the second sliding block 151, which has received a power from the second motor 152, to one side (e.g., downward direction) of the first direction Z. In addition, the second cylinder 153 may move to the other side (e.g., right direction) of the second direction X in accordance with backward movement of the second sliding block 151 to the other side (e.g., upward direction) of the first direction Z.

The second cylinder 153 may be connected to the first side cavity 120. Therefore, the position of the first side cavity 120 in the second direction X may be changed in accordance with movement of the second cylinder 153 in the second direction X. The position of the first side cavity 120 in the second direction X may determine a width of the mold body in the second direction X, which covers the molding target 400. For example, when the second sliding block 151 receives a large amount of power from the second motor 152, the second sliding block 151 may move forward (e.g., move in downward direction) in the first direction Z with a large width or distance. Therefore, the second cylinder 153 may move to one side (e.g., left direction) of the second direction X with a large width or distance. In this way, when the second cylinder 153 moves in the second direction X with a large width, the width of the mold body in the second direction X, which covers the molding target 400, may be small.

Meanwhile, when the second sliding block 151 receives less power from the second motor 152, the second sliding block 151 may move forward (e.g., downward direction) in the first direction at a relatively small width or distance. Therefore, the second cylinder 153 may move in the second direction X at a relatively small width or distance. When the second cylinder 153 moves in the second direction X at a small width, the width of the mold body in the second direction X, which covers the molding target 400, may be relatively large. That is, the width of the mold body in the second direction X may be determined in accordance with the degree of the second sliding block 151 entering the inclined surface in a sliding manner by rotating the second motor 152.

As described above, in the molding apparatus 1000 for fabricating a semiconductor package according to some embodiments, the position of the first side cavity 120 and the second side cavity 130 in the second direction X may be adjusted by the second driving part 150 and the third driving part 160, which are operated by a wedge mechanism, whereby the width of the mold body in the second direction X, which covers the molding target 400, may be set in various ways.

The bottom cavity 210 may be disposed to face the upper cavity 110. The molding target 400 may be placed on the bottom cavity 210. In some embodiments, the molding target 400 may be a semiconductor package that includes a package substrate 410 and at least one semiconductor chip 420, but the present disclosure is not limited thereto. The molding target 400 may further include other components in addition to the package substrate 410 and the semiconductor chip 420. Hereinafter, the case that the molding target 400 includes a package substrate 410 and two semiconductor chips 420 packaged on the package substrate will be described as an example. The semiconductor chip 420 may be packaged on the package substrate 410 by a flip chip bonding method or a die attach film method, but the present disclosure is not limited thereto. In addition, the case that two semiconductor chips 420 are packaged on one package substrate 410 is shown in FIG. 1 as an example, but the present disclosure is not limited thereto, and the number of semiconductor chips packaged on the package substrate 410 may be three or more.

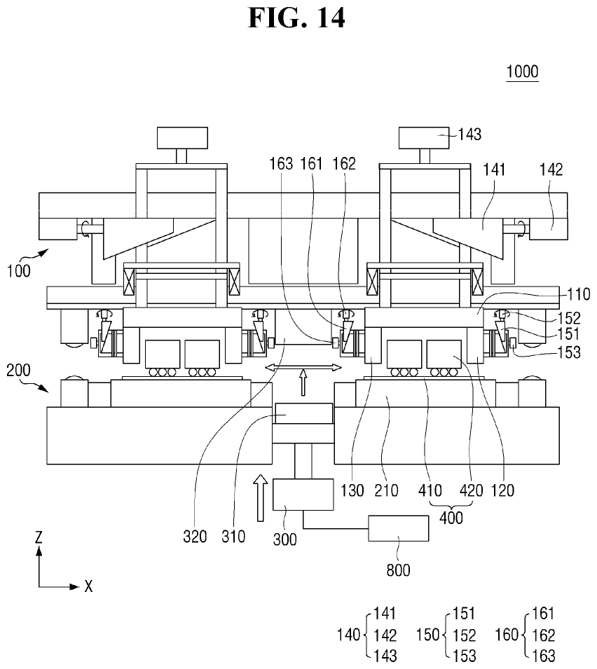

The molding material supply unit 300 may supply a molding material 310 inside the upper cavity 110, the first side cavity 120 and the second side cavity 130. When the upper mold 100 and the bottom mold 200 are clamped, the molding material supply unit 300 may move to the other side (e.g., upward direction) of the first direction Z so that the molding material 310 may be compressed by a pressure supply unit or pressure supply system 320. The molding material 310 may include, for example, an insulating polymer material such as an epoxy molding compound (EMC), and may include a filler and a resin. When the molding material 310 is compressed by the pressure supply unit 320 in a high temperature environment, its viscosity is lowered so that the molding material 310 may have fluidity. Therefore, the molding material 310 may flow to the left and right to be supplied inside the upper cavity 110, the first side cavity 120 and the second side cavity 130. An operation of supplying the molding material 310 inside the upper cavity 110, the first side cavity 120 and the second side cavity 130 by the molding material supply unit 300 during a molding forming process will be described below with reference to FIG. 14.

As described above, in the molding apparatus 1000 for fabricating a semiconductor package according to some embodiments, various modifications may be made in a dimension of the mold body, which covers the molding target 400, in the first direction Z and the second direction X depending on a size of the molding target 400. Therefore, restrictions according to the size of the molding target 400 are resolved, so that a mold for forming a dedicated molding for each molding target 400 is unnecessary, and the molding target 400 may be used as a mold for general purpose of use. Also, the position of the upper cavity 110 in the first direction Z and the position of the first side cavity 120 and the second side cavity 130 in the second direction X may be adjusted in accordance with the size of the molding target 400, whereby use of the molding material 310 may be reduced. In addition, a width in the second direction X between the first side cavity 120 and the second side cavity 130 may be set in accordance with the size of the molding target 400 in the second direction X, whereby a void trap may be prevented from being formed on the mold body due to the flow of the molding material 310 to the outside of the semiconductor chip 420.

Although FIG. 1 shows that the positions of the upper cavity 110, the first side cavity 120 and the second side cavity 130 are adjusted by the first driving part 140, the second driving part 150 and the third driving part 160 which are connected to the upper cavity 110, the first side cavity 120 and the second side cavity 130, respectively, the present disclosure is not limited thereto. For example, in the molding apparatus 1000 for fabricating a semiconductor package according to some embodiments, the first driving part 140 is not connected to the upper cavity 110 but the second driving part 150 and the third driving part 160 are connected to the first side cavity 120 and the second side cavity 130, respectively, so that the height of the mold body in the first direction Z is fixed and only a thickness of the mold body in the second direction X may be adjusted. Also, in some embodiments, the second driving part 150 or the third driving part 160 may be connected to only one of the first side cavity 120 and the second side cavity 130.

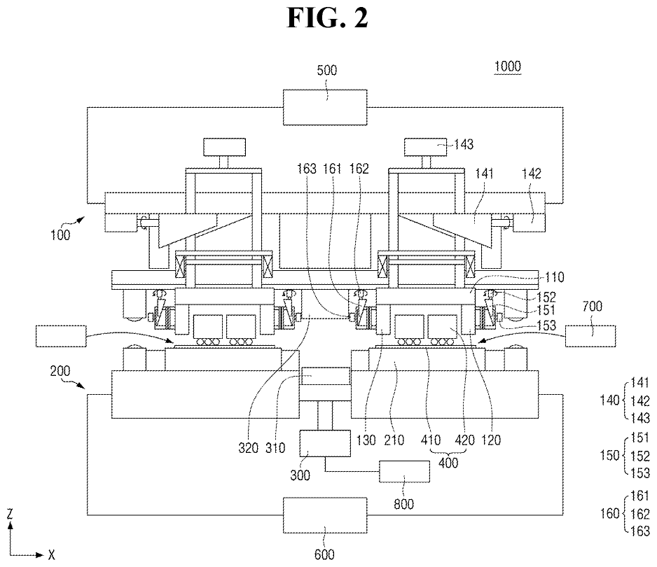

Next, referring to FIG. 2, the upper mold 100 may reciprocate in the first direction Z by a first loader 500. In addition, the bottom mold 200 may reciprocate in the first direction Z by a second loader 600. In the molding forming process of the molding apparatus 1000 for fabricating a semiconductor package, the upper mold 100 may move to one side (e.g., downward direction) of the first direction Z by the first loader 500 and the bottom mold 200 may move to the other side (e.g., upward direction) of the first direction Z by the second loader 600, so that the upper mold 100 and the bottom mold 200 may be clamped.

Also, in some embodiments, the molding target 400 may be placed on the bottom cavity 210 by a third loader or a carrier 700. When the upper mold 100 and the bottom mold 200 are clamped, the molding material supply unit 300 may move to the other side (e.g., upward direction) of the first direction Z by a fourth loader 800, so that the molding material 310 may be compressed by the pressure supply unit 320.

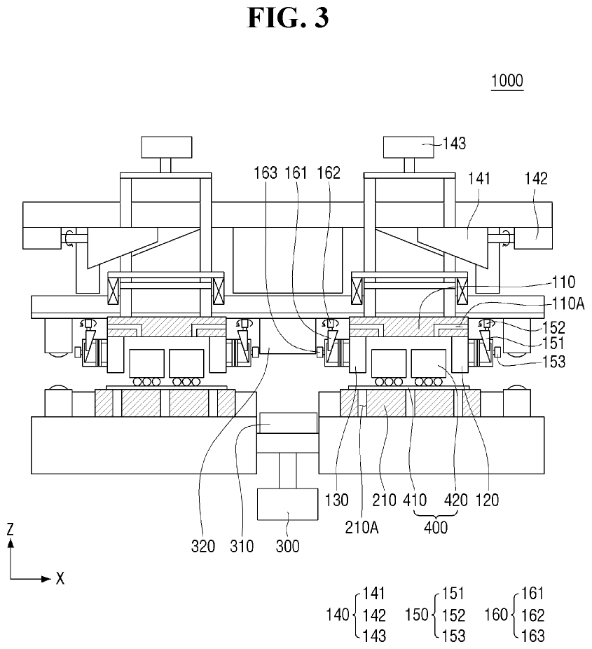

Next, referring to FIG. 3, in some embodiments, at least one first vacuum generation unit or first vacuum generation system 110A may be formed inside the upper cavity 110. The at least one first vacuum generation unit 110A may include one or more first vacuum channels defined in the upper cavity 110. The first vacuum generation unit 110A may perform vacuum suction so that an inner side of an inner intaglio of the upper cavity 110 is close to a vacuum state, in order to prevent a void trap from being generated inside the mold body when the mold body is formed in the inner intaglio of the upper cavity 110. For example, the first vacuum generation unit 110A may perform vacuum suction so that an air pressure inside the inner intaglio of the upper cavity 110 is maintained to be less than 10 torr.

In some embodiments, at least one second vacuum generation unit or second vacuum generation unit system 210A may be formed inside the bottom cavity 210. The at least one second vacuum generation unit 210A may include one or more second vacuum channels defined in the bottom cavity 210. The second vacuum generation unit 210A may adsorb a lower surface of the molding target 400 on the bottom cavity 210 by performing vacuum suction so that the molding material does not flow between the bottom cavity 210 and the molding target 400 when the molding target 400 is placed on the bottom cavity 210.

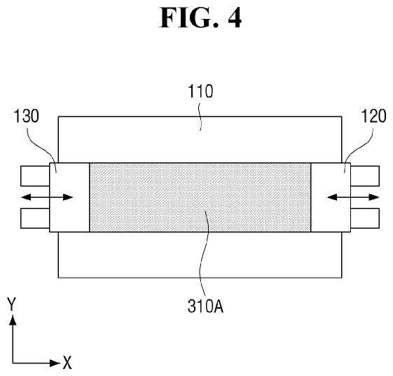

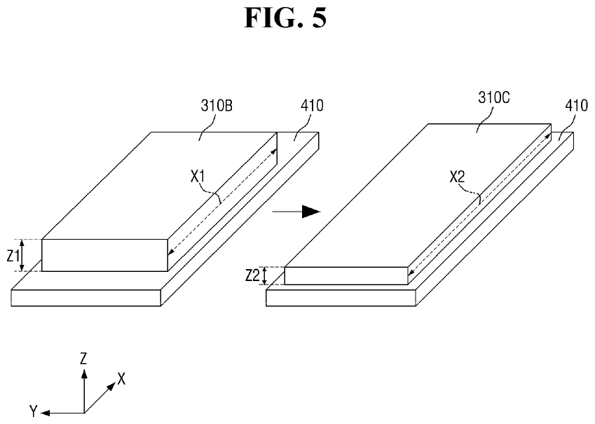

FIG. 4 is a cross-sectional view taken along line I-I of FIG. 1. FIG. 5 is an example diagram illustrating an effect of the molding apparatus for fabricating a semiconductor package in FIG. 1

Referring to FIG. 4, a width of a mold body 310A in the second direction X, which is generated as a result of the molding forming process of the molding apparatus 1000 (shown in FIG. 1) for fabricating a semiconductor package, may be changed as the first side cavity 120 and the second side cavity 130 move in the second direction X.

Next, referring to FIG. 5, a width or height Z1 of a mold body 310B, which is generated as a result of the molding forming process of the molding apparatus 1000 (shown in FIG. 1) for fabricating a semiconductor package, in the first direction Z and a width X1 of the mold body 310B in the second direction X may be changed to a mold body 310C having a width or height Z2 in the first direction Z and a width X2 in the second direction X.

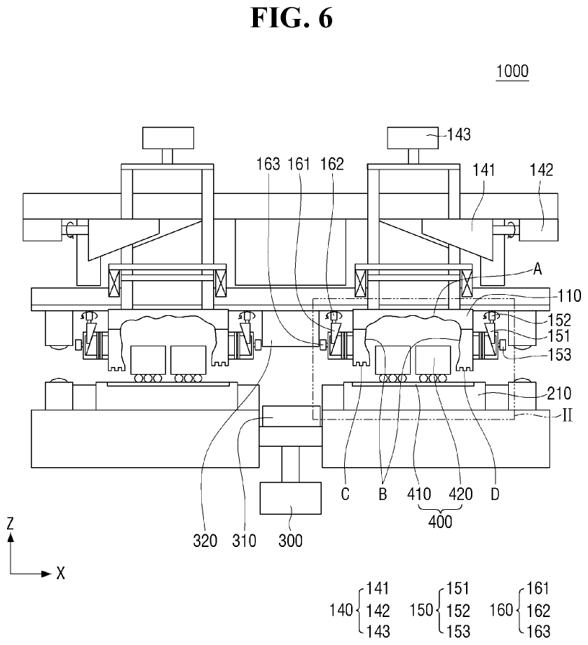

FIG. 6 is an example view illustrating a structure in which an intaglio is formed inside an upper cavity, side cavities and a bottom cavity of the molding apparatus for fabricating the semiconductor package of FIG. 1.

Referring to FIG. 6, in some embodiments, an intaglio A may be formed in the upper cavity 110. Therefore, when the molding apparatus 1000 for fabricating a semiconductor package performs the molding forming process, a molding material may be injected into the inner intaglio of the upper cavity 110 to form a mold body covering the molding target 400. A shape of the inner intaglio of the upper cavity 110 shown in FIG. 6 is an example, and may be varied depending on the embodiments.

In some embodiments, an intaglio B may be formed inside the first side cavity 120 and the second side cavity 130. Therefore, when the molding apparatus 1000 for fabricating a semiconductor package performs a molding process, a molding material 310 may be injected into each inner intaglio of the first side cavity 120 and the second side cavity 130 to form a mold body covering the molding target 400. A shape of the intaglio formed inside the first side cavity 120 and the second side cavity 130 is not limited to that shown in FIG. 6, and may be varied depending on the embodiments.

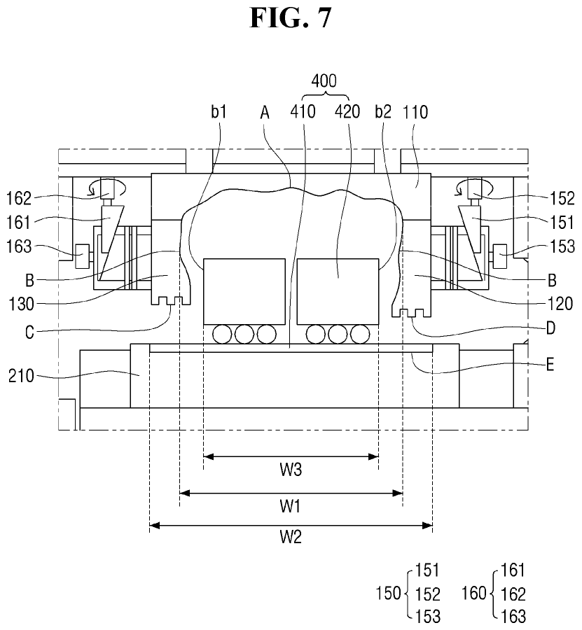

In some embodiments, an intaglio C may be formed at a lower portion of the second side cavity 130. In addition, an intaglio D may be formed at a lower portion of the first side cavity 120. The intaglio C formed at the lower portion of the second side cavity 130 and the intaglio D formed at the lower portion of the first side cavity 120 will be described below with reference to FIG. 7.

In some embodiments, an intaglio may be formed inside the bottom cavity 210. For example, when a horizontal width, a vertical width and a height of the package substrate 410 are a, b and c, respectively, as shown in FIG. 7, an intaglio or recess E having a horizontal width ‘a’, a vertical width ‘b’ and a height ‘c’ may be formed on an upper surface of the bottom cavity 210. Therefore, when the molding apparatus 1000 for fabricating a semiconductor package performs the molding process, a package substrate 410 may be disposed in the inner intaglio E of the bottom cavity 210, but the present disclosure is not limited thereto. The bottom cavity 210 may have a structure in which an intaglio is not formed therein. The package substrate 410 may be disposed on the upper surface of the bottom cavity 210.

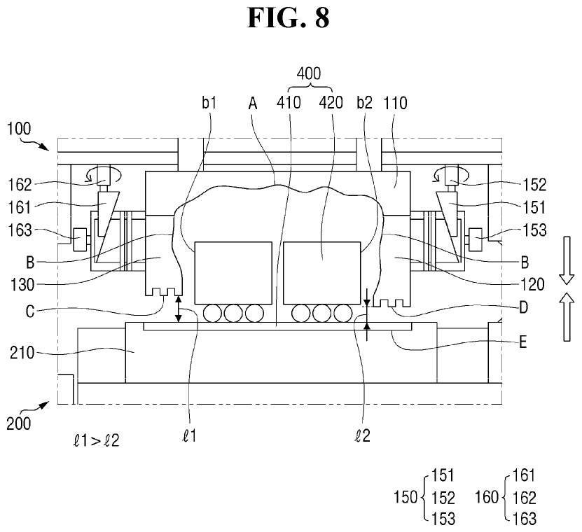

FIG. 7 is an enlarged view illustrating portion II of FIG. 6. FIG. 8 is a view illustrating a structure in which an upper mold and a bottom mold of FIG. 7 are clamped.

Referring to FIG. 7, an intaglio D and an intaglio C of a saw-toothed wheel shape may be formed at the lower portions of the first side cavity 120 and the second side cavity 130, but the present disclosure is not limited thereto. Shapes of the intaglio D and the intaglio C, which are formed at the lower portions of the first side cavity 120 and the second side cavity 130, may be varied depending on the embodiments.

Also, in some embodiments, a width W1 in the second direction X between the first side cavity 120 and the second side cavity 130 may be smaller than a width W2 of the package substrate 410 in the second direction X. In this case, the width W1 in the second direction X between the first side cavity 120 and the second side cavity 130 may correspond to a maximum distance between the inside intaglios when the intaglio is formed inside the first side cavity 120 and the second side cavity 130, respectively. The width W1 in the second direction X between the first side cavity 120 and the second side cavity 130 may be adjusted by the second driving part 150 connected to the first side cavity 120 and the third driving part 160 connected to the second side cavity 130, as described above in reference to FIG. 1.

Also, the width W1 in the second direction X between the first side cavity 120 and the second side cavity 130 may be greater than a width W3 in the second direction X between a first boundary or side b1 and a second boundary or side b2 of the semiconductor chip 420. At this time, the first boundary b1 and the second boundary b2 may correspond to the outermost boundary of at least one semiconductor chip 420 included in the molding target 400. The first boundary b1 and the second boundary b2 may correspond to opposite sides of the at least one semiconductor chip 420.

As described above, in some embodiments, the width W1 in the second direction X between the first side cavity 120 and the second side cavity 130 is smaller than the width W2 of the package substrate 410 in the second direction X, so that the molding material may be prevented from flowing to the outside of the package substrate 410 to prevent a dummy mold body from being formed. Therefore, unnecessary usage of the molding material may be reduced, and a subsequent process step of removing the dummy mold body may be omitted.

The width W1 in the second direction X between the first side cavity 120 and the second side cavity 130 may be greater than the width W3 in the second direction X between the first boundary b1 and the second boundary b2 of the semiconductor chip 420. Therefore, the mold body may be formed to completely cover the semiconductor chip 420.

Next, referring to FIG. 8, when the upper mold 100 and the bottom mold 200 are clamped, the lower surface of the second side cavity 130 and the upper surface of the package substrate 410 may be spaced apart from each other as much as a predetermined distance or more. In some embodiments, when the upper mold 100 and the bottom mold 200 are clamped, the lower surface of the second side cavity 130 and the upper surface of the package substrate 410 may be spaced apart from each other as much as l1. Therefore, when the molding material 310 compressed by the pressure supply unit 320 to have fluidity flows to the right, the molding material 310 may smoothly pass between the lower surface of the second side cavity 130 and the upper surface of the package substrate 410 and then may be supplied into the upper cavity 110, the first side cavity 120 and the second side cavity 130.

In some embodiments, when the upper mold 100 and the bottom mold 200 are clamped, the lower surface of the first side cavity 120 and the upper surface of the package substrate 410 may be spaced apart from each other as much as l2. Also, when the upper mold 100 and the bottom mold 200 are clamped, the distance l2 between the lower surface of the first side cavity 120 and the upper surface of the package substrate 410 may be smaller than the distance l1 between the lower surface of the second side cavity 130 and the upper surface of the package substrate 410.

For example, when the upper mold 100 and the bottom mold 200 are clamped, the distance l1 between the lower surface of the second side cavity 130 and the upper surface of the package substrate 410 may be 100 μm. Also, when the upper mold 100 and the bottom mold 200 are clamped, the distance l2 between the lower surface of the first side cavity 120 and the upper surface of the package substrate 410 may be 20 μm to 30 μm.

Therefore, when a mold body is formed inside the first side cavity 120, the molding material 310 may be adjusted to stop at a desired position without flowing to the outside of the first side cavity 120. Therefore, the molding material 310 may prevent the dummy mold body from being formed due to the flow to the outside of the first side cavity 120, thereby reducing unnecessary usage of the molding material 310 and omitting a subsequent process step of removing the dummy mold body. As described above, when the upper mold 100 and the bottom mold 200 are clamped, the first side cavity 120 and the package substrate 410 may be spaced apart from each other so that the molding material cannot pass between the lower surface of the first side cavity 120 and the upper surface of the package substrate 410 but air may pass therebetween. As a result, vacuum suction may be performed during the molding forming process so that the inside of the upper cavity 110, the first side cavity 120 and the second side cavity 130 is close to a vacuum state, whereby a void trap may be prevented from being generated inside the mold body.

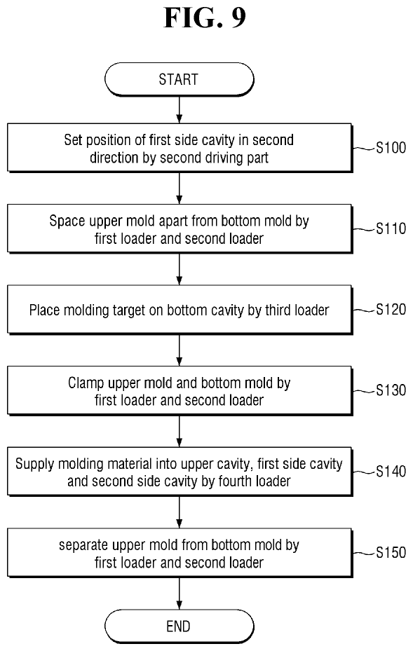

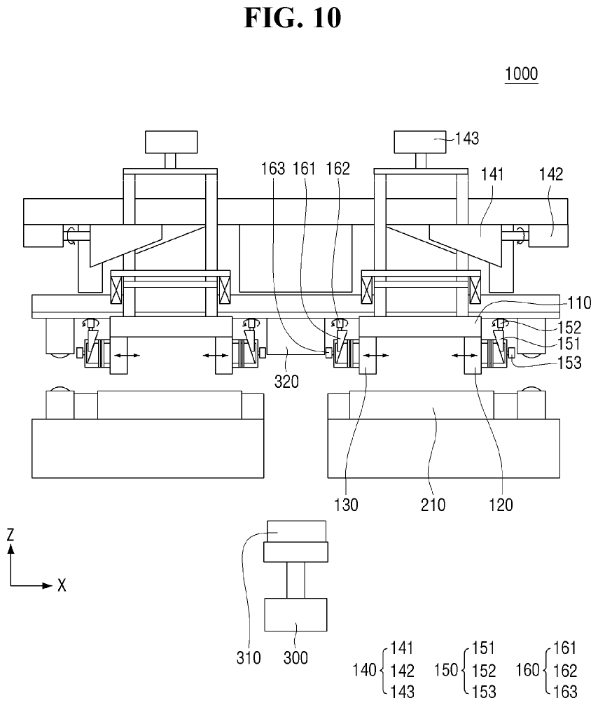

FIG. 9 is a flow chart illustrating a molding method of a semiconductor package according to some embodiments. FIGS. 10 to 15 are views illustrating intermediate steps to describe a molding method of a semiconductor package according to some embodiments. Hereinafter, the molding method of a semiconductor package according to some embodiments will be described with reference to FIGS. 9 to 15.

Referring to FIGS. 9 and 10, the position of the first side cavity 120 in the second direction X is set by the second driving part 150 (S100). At this time, the position of the side cavity 120 in the second direction X may be set by the second driving part 150 operated by a wedge mechanism, but the present disclosure is not limited thereto. The position of the first side cavity 120 in the second direction X may be set by the second driving part 150 operated by all operation mechanisms suitable for moving the first side cavity 120 in the second direction X.

For example, when the second motor 152 is rotated by an amount corresponding to the preset position of the first side cavity 120 in the second direction X, the second sliding block 151 connected to the second motor 152 may move forward to one side (e.g., downward direction) of the first direction Z. In this case, the second cylinder 153 connected to the second sliding block 151 may move to one side (e.g., left direction) of the second direction X in accordance with forward movement of the second sliding block 151 to one side of the first direction Z. In addition, the first side cavity 120 may move to one side (e.g., left direction) of the second direction X in accordance with movement of the second cylinder 153 to one side of the second direction X, so that the first side cavity 120 may be disposed at a preset position in the second direction X.

In some embodiments, the position of the second side cavity 130 in the second direction X may be also set by the third driving part 160. The second side cavity 130 may also be moved in the second direction X by the same operation method as that of the first side cavity 120. Also, in some embodiments, the position of the upper cavity 110 in the first direction Z may be also set by the first driving part 140.

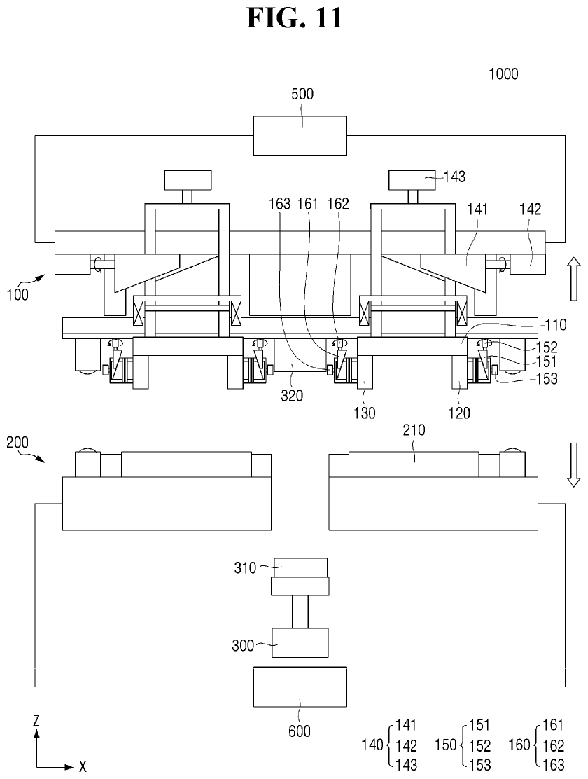

Next, referring to FIGS. 9 and 11, the upper mold 100 and the bottom mold 200 are spaced apart from each other by the first loader 500 for moving the upper mold 100 in the first direction Z and the second loader 600 for moving the bottom mold 200 in the first direction Z (S110). This step is to make sure of a space between the upper mold 100 and the bottom mold 200 in order to seat the molding target 400 (shown in FIG. 1) on the bottom cavity 210 in a subsequent process step.

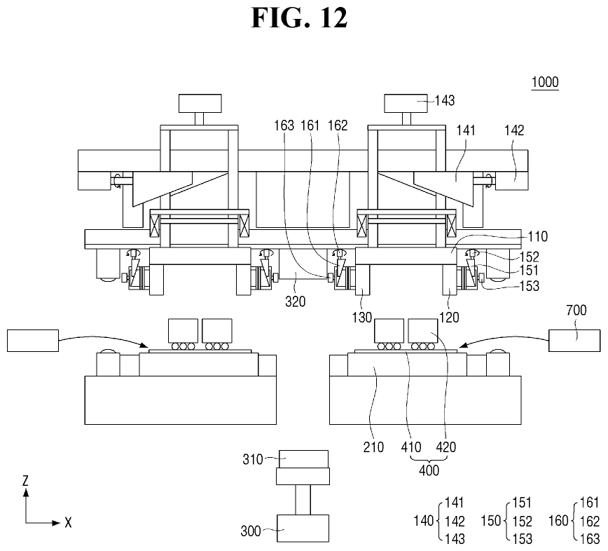

Next, referring to FIGS. 9 and 12, the molding target 400 is placed on the bottom cavity 210 by the third loader 700 (S120). At this time, the molding target 400 may be placed on the bottom cavity 210 so that at least one semiconductor chip 420, which is the molding target 400, is disposed inside the intaglio of the upper cavity 110, the first side cavity 120 and the second side cavity 130. Therefore, when the molding material is cured to form the mold body, the mold body may fully cover the at least one semiconductor chip 420. In addition, when the intaglio is formed inside the bottom cavity 210 (shown in FIG. 6), the molding target 400 may be disposed at the inner intaglio of the bottom cavity 210.

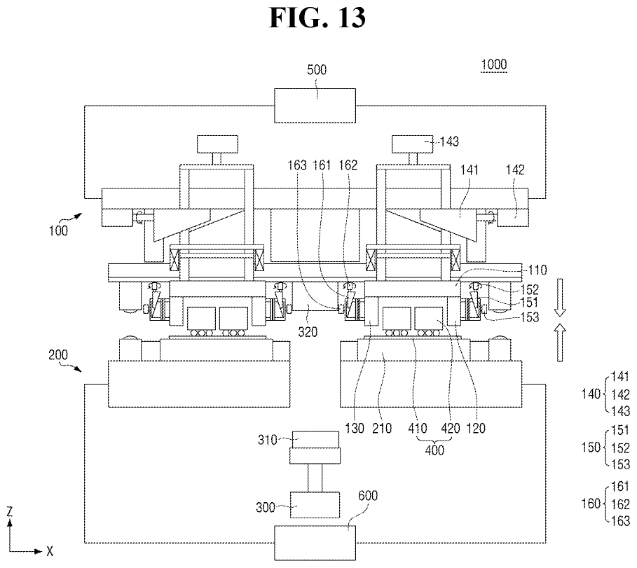

Next, referring to FIGS. 9 and 13, the upper mold 100 is moved to one side (e.g., downward direction) of the first direction Z by the first loader 500 and the bottom mold 200 is moved to the other side (e.g., upward direction) of the first direction Z by the second loader 600, whereby the upper mold 100 and the bottom mold 200 are clamped (S130).

Next, referring to FIGS. 9 and 14, the molding material is supplied inside the upper cavity 110, the first side cavity 120 and the second side cavity 130 by the fourth loader 800 (S140). The fourth loader 800 may move the molding material supply unit 300 to the other side (e.g., upward direction) of the first direction Z.

In some embodiments, a hole into which the molding material 310 is inserted may be formed on an upper surface of the molding material supply unit 300. For example, when the molding material 310 is EMC, an EMC tablet which is in a state before being cured may be inserted into the hole on the upper surface of the molding material supply unit 300. Before the upper surface of the package substrate 410 and the lower surfaces of the first side cavity 120 and the second side cavity 130 are completely clamped by movement of the upper mold 100 and the bottom mold 200 in the first direction Z, the fourth loader 800 may move the molding material supply unit 300 to the other side (e.g., upward direction) of the first direction Z, whereby the EMC tablet may be compressed by the pressure supply unit 320. When a high pressure is applied to the EMC tablet in a high-temperature environment of 170° C. to 180° C., the EMC tablet may be phase-changed into a liquid state. Therefore, the EMC tablet compressed by the pressure supply unit 320 may flow to the left and right and then supplied inside the upper cavity 110, the first side cavity 120 and the second side cavity 130.

In some embodiments, when the upper mold 100 and the bottom mold 200 are clamped, the lower surface of the second side cavity 130 and the upper surface of the package substrate 410 may be spaced apart from each other as much as l1 (shown in FIG. 8). Therefore, when the EMC of the liquid state flows to the right, the EMC may be supplied inside the upper cavity 110, the first side cavity 120 and the second side cavity 130 by smoothly passing between the lower surface of the second side cavity 130 and the upper surface of the package substrate 410.

Also, when the upper mold 100 and the bottom mold 200 are clamped, the lower surface of the first side cavity 120 and the upper surface of the package substrate 410 may be spaced apart from each other as much as l2 so that vacuum suction may be performed. Therefore, vacuum suction may be performed so that the inside of the upper cavity 110, the first side cavity 120 and the second side cavity 130 is close to a vacuum state, whereby a void trap may be prevented from being generated inside the mold body. Further, in some embodiments, l2 may be smaller than l1. Therefore, the EMC may be adjusted to stop at a desired position without flowing to the outside of the first side cavity 120 and the package substrate 410. As a result, the dummy mold body may be prevented from being formed due to the flow of the molding material to the outside of the package substrate 410, whereby unnecessary usage of the molding material may be reduced, and a subsequent process step of removing the dummy mold body may be omitted.

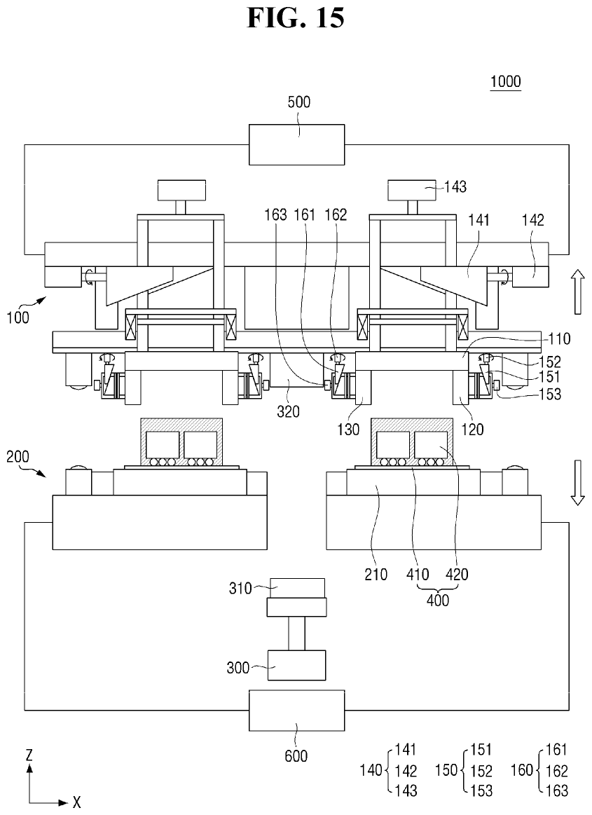

Next, referring to FIGS. 9 and 15, after the EMC is supplied inside the upper cavity 110, the first side cavity 120 and the second side cavity 130 and a preset curing time passes, the upper mold 100 and the bottom mold 200 are separated from each other by the first loader 500 and the second loader 600 (S150). In this case, the preset curing time is required for the EMC to be phase-changed from a liquid state to a solid state, and may be, for example, 100 seconds to 300 seconds, but the present disclosure is not limited thereto.

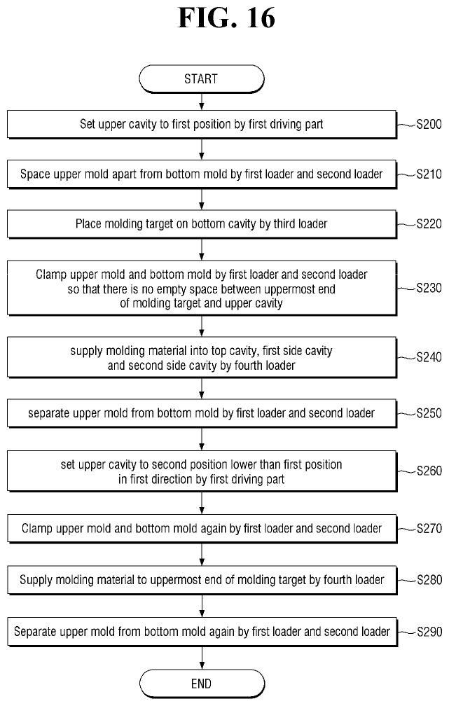

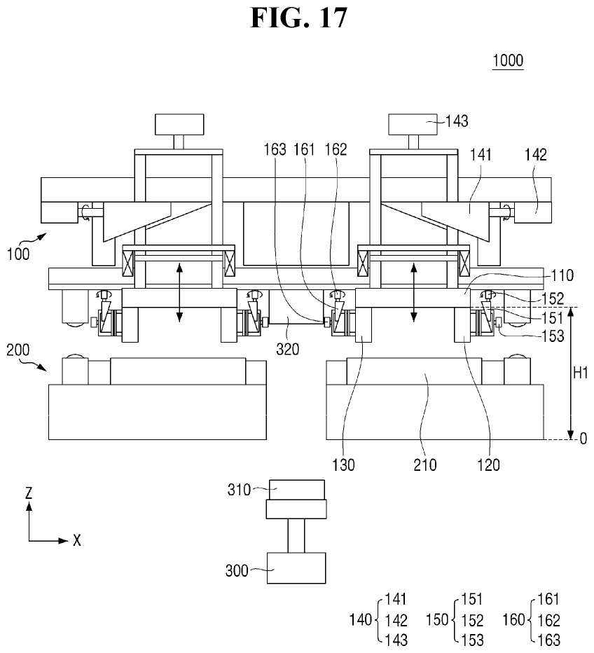

FIG. 16 is a flow chart illustrating a molding method of a semiconductor package according to some embodiments. FIGS. 17 to 26 are views illustrating intermediate steps to describe a molding method of a semiconductor package according to some embodiments. Hereinafter, the molding method of a semiconductor package according to some embodiments will be described with reference to FIGS. 16 to 26, and a redundant description of the aforementioned description will be omitted and the following description will be based on differences from the aforementioned description in the interest of brevity.

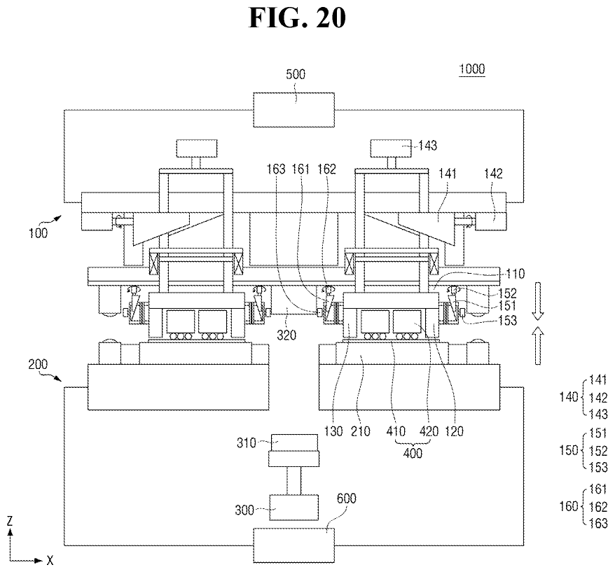

Referring to FIGS. 16 and 17, the position of the upper cavity 110 in the first direction Z is set to a first position H1 by the first driving part 140 (S200). In some embodiments, the first position H1 of the upper cavity 110 in the first direction Z may be set so that there is no empty space between the uppermost end of the molding target 400 and the upper cavity 110 when the upper mold 100 and the bottom mold 200 are clamped. This will be described below with reference to FIG. 20. In some embodiments, the position of the first side cavity 120 in the second direction X and the position of the second side cavity 130 in the second direction X may be set by the second driving part 150 and the third driving part 160, respectively.

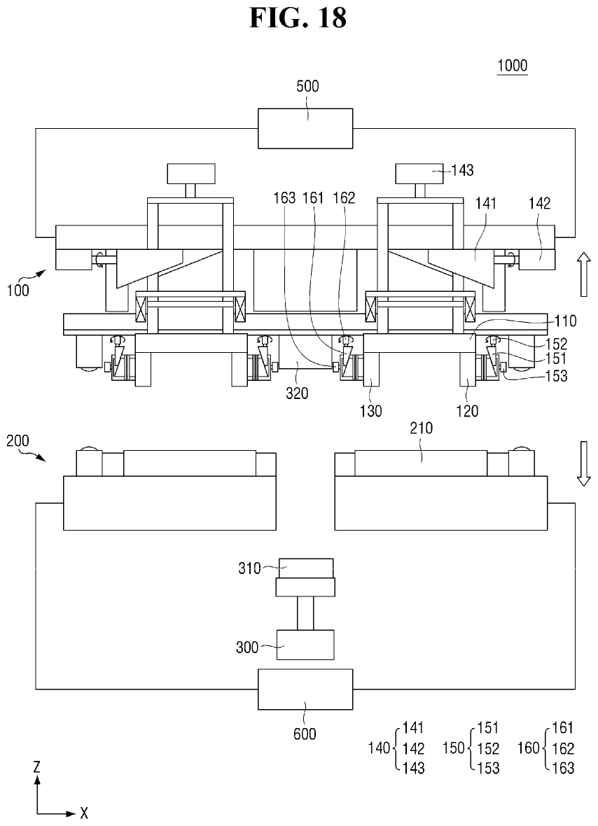

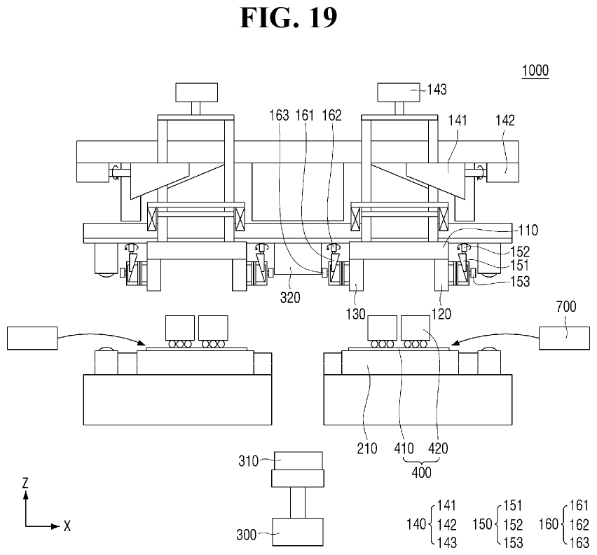

Next, referring to FIGS. 16 and 18, the upper mold 100 and the bottom mold 200 are spaced apart from each other by the first loader 500 for moving the upper mold 100 in the first direction Z and the second loader 600 for moving the bottom mold 200 in the first direction Z (S210). Next, referring to FIGS. 16 and 19, the molding target is placed on the bottom cavity 210 by the third loader 700 (S220).

Referring to FIGS. 16 and 20, the upper mold 100 is moved in the first direction Z by the first loader 500 and the bottom mold 200 is moved in the first direction Z by the second loader 600 so that the upper mold 100 and the bottom mold 200 are clamped (S230). At this time, the upper mold 100 and the bottom mold 200 may be clamped so that there is no empty space or substantially no empty space between the uppermost end of the molding target 400 and the upper cavity 110. For example, when the upper mold 100 and the bottom mold 200 are clamped, an empty space between the uppermost end of the semiconductor chip 420 included in the molding target 400 and the upper cavity 110 may be little formed. However, as shown in FIG. 20, a slight margin may be formed between the uppermost end of the semiconductor chip 420 included in the molding target 400 and the upper cavity 110 depending on the embodiments. In some embodiments, substantially no empty space may mean that the uppermost end of the molding target 400 and the upper cavity 110 are spaced apart no more than the dimension l2 described herein (e.g., 20 μm or less or 30 μm or less).

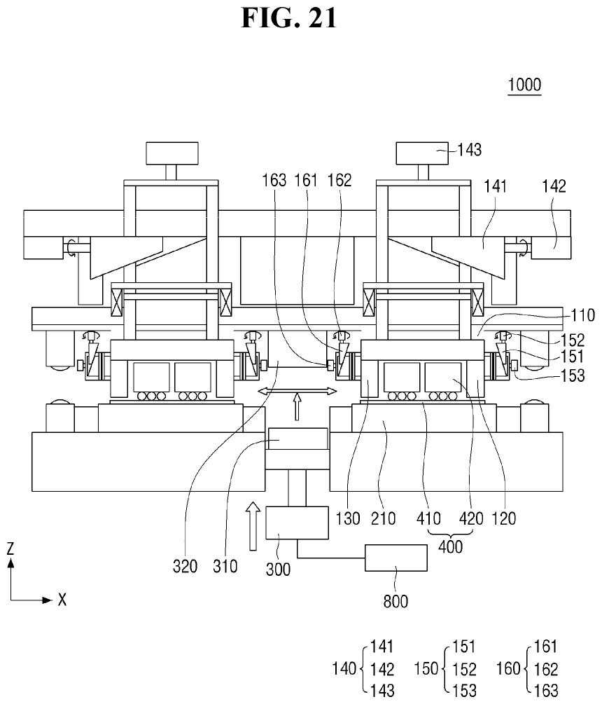

Referring to FIGS. 16 and 21, a molding material is supplied inside the upper cavity 110, the first side cavity 120 and the second side cavity 130 by the fourth loader 800 or by the molding material supply unit 300 (S240). The fourth loader 800 may move the molding material supply unit 300 to the other side (e.g., upward direction) of the first direction Z so that the molding material 310 may be compressed by the pressure supply unit 320. In a high-temperature environment of 170° C. to 180° C., when the molding material (e.g., EMC tablet) compressed by the pressure supply unit 320 is phase-changed into a liquid state and flows to the right, a space between the lower surface of the semiconductor chip 420 and the upper surface of the package substrate 410 is larger than the empty space between the uppermost end of the molding target 400 and the upper cavity 110 and thus most of the EMC may flow to the space between the lower surface of the semiconductor chip 420 and the upper surface of the package substrate 410.

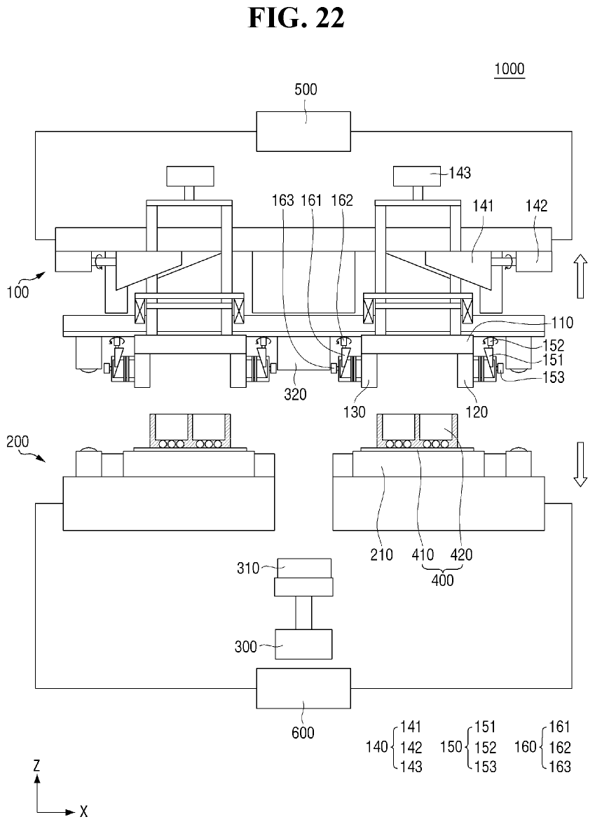

Referring to FIGS. 16 and 22, after the molding material (e.g., EMC) is supplied to the inside of the upper cavity 110, the first side cavity 120 and the second side cavity 130 and a preset curing time passes, the upper mold 100 and the bottom mold 200 are separated from each other by the first loader 500 and the second loader 600 (S250).

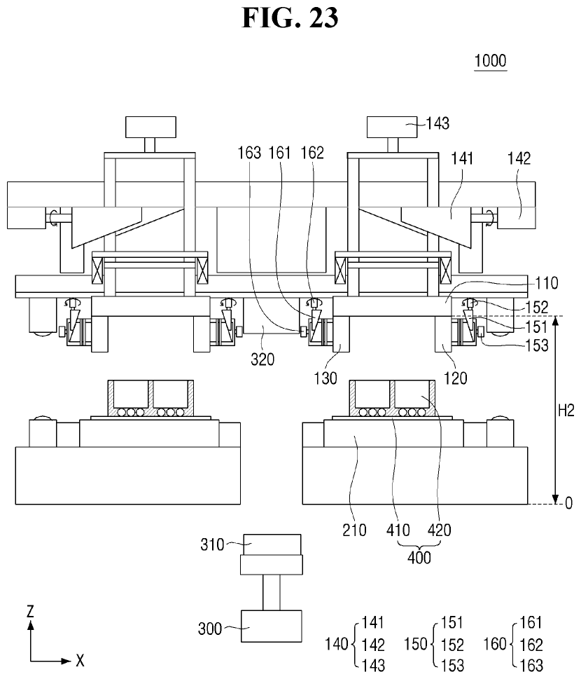

Referring to FIGS. 16 and 23, the position of the upper cavity 110 in the first direction Z is set to a second position H2 by the first driving part 140 (S260). In some embodiments, the second position H2 of the upper cavity 110 may be higher in the first direction Z than the first position H1. Therefore, in the case that the upper cavity 110 is set to the second position H2, a larger empty space may be formed between the uppermost end of the molding target 400 and the upper cavity 110 when the upper mold 100 and the bottom mold 200 are clamped, than in the case that the upper cavity 110 is set to the first position H1.

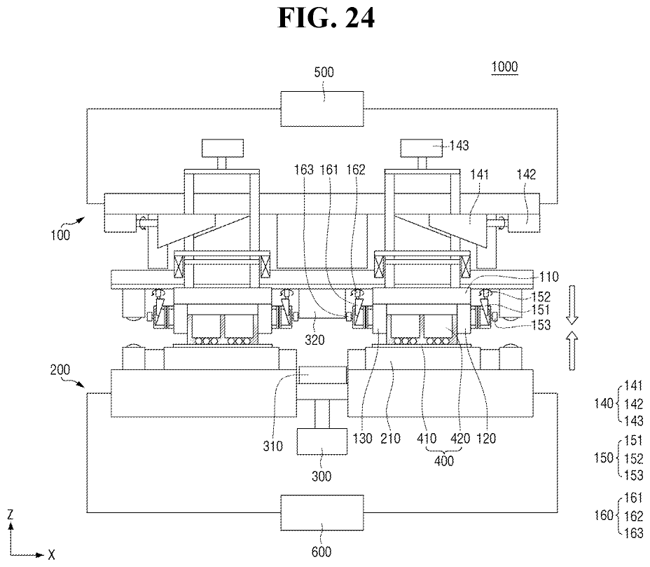

Referring to FIGS. 16 and 24, the upper mold 100 is moved to one side (e.g., downward direction) of the first direction Z by the first loader 500 and the bottom mold 200 is moved to the other side (e.g., upward direction) of the first direction Z by the second loader 600, so that the upper mold 100 and the bottom mold 200 are clamped again (S270). In this case, as shown in FIG. 24, an empty space may be formed between the uppermost end of the molding target 400 and the upper cavity 110.

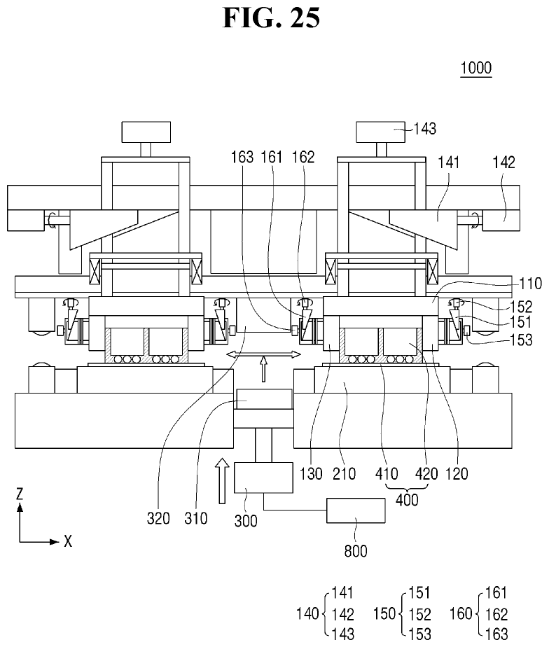

Referring to FIGS. 16 and 25, the molding material 310 is supplied to the uppermost end of the molding target 400 by the fourth loader 800 (S280). The fourth loader 800 may move the molding material supply unit 300 to the other side (e.g., upward direction) of the first direction Z so that the molding material 310 may be compressed by the pressure supply unit 320. That is, in a high temperature environment of 170° C. to 180° C., when the molding material (e.g., EMC tablet) compressed by the pressure supply unit 320 is phase-changed into a liquid state and flows to the right, since a mold body, which is already cured to have a low viscosity, is formed in the space between the lower surface of the semiconductor chip 420 and the upper surface of the package substrate 410, most of the EMC of a high viscosity state may flow to the empty space between the uppermost end of the molding target 400 and the upper cavity 110.

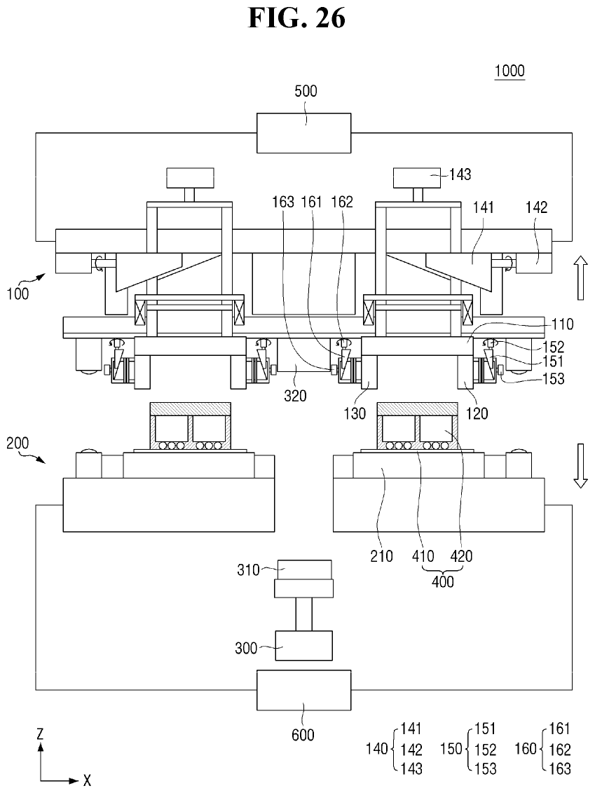

Referring to FIGS. 16 and 26, after the molding material (e.g., EMC) is supplied to the uppermost end of the molding target 400 and a preset curing time passes, the upper mold 100 and the bottom mold 200 are separated from each other again by the first loader 500 and the second loader 600 (S290).

As described above, the mold body is first formed between the lower surface of the semiconductor chip 420 having a relatively narrow space and the upper surface of the package substrate 410 and then the position of the upper cavity 110 in the first direction Z is reset so that the mold body may be finally formed between the uppermost end of the molding target having a relatively wide space and the upper cavity 110. Therefore, a void trap may be prevented from being generated between the lower surface of the semiconductor chip 420 and the upper surface of the package substrate 410.

Although the embodiments of the present disclosure have been described above with reference to the accompanying drawings, the present disclosure may not be limited to the embodiments and may be implemented in various different forms. Those of ordinary skill in the technical field to which the present disclosure belongs will be able to understand that the present disclosure may be implemented in other specific forms without changing the technical idea or essential features of the present disclosure. Therefore, it should be understood that the embodiments as described above are illustrative in all respects and are not restrictive.

What is claimed is:

1. A molding apparatus for fabricating a semiconductor package, the molding apparatus comprising:
an upper mold including an upper cavity, a first side cavity at a first side of the upper cavity, a second side cavity formed at an opposite second side of the upper cavity, and a first driving part connected to the first side cavity and configured to move the first side cavity in a first direction; and
a bottom mold including a bottom cavity configured to receive a molding target including a package substrate and at least one semiconductor chip,
wherein a width in the first direction between the first side cavity and the second side cavity is smaller than a width of the package substrate in the first direction and greater than a width in the first direction between a first boundary and a second boundary of the at least one semiconductor chip.

2. The molding apparatus of claim 1, wherein the first driving part includes a first sliding block configured to move in a second direction, a first motor connected to the first sliding block and configured to drive the first sliding block in the second direction, and a first cylinder connected to the first sliding block and movably mounted in the first direction in accordance with movement of the first sliding block in the second direction.

3. The molding apparatus of claim 2, wherein the first sliding block includes an inclined surface for adjusting a position of the first cylinder in the first direction.

4. The molding apparatus of claim 2, wherein the upper mold includes a second driving part connected to the second side cavity and configured to move the second side cavity in the first direction.

5. The molding apparatus of claim 4, wherein the second driving part includes a second sliding block configured to move in the second direction, a second motor connected to the second sliding block and configured to drive the second sliding block in the second direction, and a second cylinder connected to the second sliding block and movably mounted in the first direction in accordance with movement of the second sliding block in the second direction.

6. The molding apparatus of claim 1, wherein the first driving part is operated by a wedge mechanism.

7. The molding apparatus of claim 1, wherein the upper mold includes a third driving part connected to the upper cavity and configured to move the upper cavity in a second direction.

8. The molding apparatus of claim 7, wherein the third driving part includes a third sliding block configured to move in the first direction, a third motor connected to the third sliding block and configured to drive the third sliding block in the first direction, and a third cylinder connected to the third sliding block and movably mounted in the second direction in accordance with movement of the third sliding block in the first direction.

9. The molding apparatus of claim 1, further comprising a molding material supply unit configured to supply a molding material to inside of the upper cavity, the first side cavity and the second side cavity.

10. The molding apparatus of claim 1, further comprising at least one vacuum generation unit inside the upper cavity.

11. The molding apparatus of claim 1, further comprising at least one vacuum generation unit inside the bottom cavity.

12. A molding method of a semiconductor package comprising:
providing a molding apparatus for fabricating the semiconductor package, the molding apparatus comprising: a upper mold including a upper cavity, a first side cavity formed at a first side of the upper cavity, a second side cavity formed at an opposite second side of the upper cavity, a first driving part connected to the first side cavity and configured to move the first side cavity in a first direction, and a second driving part connected to the second side cavity and configured to move the second side cavity in the first direction, and a bottom mold including a bottom cavity configured to receive a molding target;
setting a position of the first side cavity in the first direction by the first driving part;
spacing the upper mold apart from the bottom mold by a first loader moving the upper mold in a second direction and/or a second loader moving the bottom mold in the second direction;
placing the molding target on the bottom cavity by a third loader;
clamping the upper mold and the bottom mold by the first loader and/or the second loader;
supplying a molding material between the upper cavity, the first side cavity, and the second side cavity by a fourth loader; and
separating the upper mold from the bottom mold by the first loader and/or the second loader,
wherein the first driving part and the second driving part are operated by a wedge mechanism.

13. The molding method of claim 12, wherein the molding target includes a package substrate and at least one semiconductor chip, and a width in the first direction between the first side cavity and the second side cavity is smaller than a width of the package substrate in the first direction and greater than a width in the first direction between a first boundary and a second boundary of the semiconductor chip.

14. The molding method of claim 13, wherein a lower surface of the first side cavity and an upper surface of the package substrate are spaced apart from each other by predetermined interval or more when the upper mold and the bottom mold are clamped.

15. The molding method of claim 12, wherein the first driving part includes a first sliding block configured to move in the second direction, a first motor connected to the first sliding block and configured to drive the first sliding block in the second direction, and a first cylinder connected to the first sliding block and movably mounted in the first direction in accordance with movement of the first sliding block in the second direction.

16. The molding method of claim 15, wherein the second driving part includes a second sliding block configured to move in the second direction, a second motor connected to the second sliding block and configured to drive the second sliding block in the second direction, and a second cylinder connected to the second sliding block and movably mounted in the first direction in accordance with movement of the second sliding block in the second direction.

17. A molding method of a semiconductor package comprising:
providing a molding apparatus for fabricating the semiconductor package, the molding apparatus comprising a upper mold including a upper cavity, a first side cavity formed at a first side of the upper cavity, a second side cavity formed at an opposite second side of the upper cavity, and a first driving part connected to the upper cavity and configured to move the upper cavity in a first direction, and a bottom mold including a bottom cavity configured to receive a molding target;
setting the upper cavity to a first position by the first driving part;
spacing the upper mold apart from the bottom mold by a first loader moving the upper mold in the first direction and/or a second loader moving the bottom mold in the first direction;
placing the molding target on the bottom cavity by a carrier;
clamping the upper mold and the bottom mold by the first loader and/or the second loader so that there is no empty space between an uppermost end of the molding target and the upper cavity;
supplying a molding material to inside of the upper cavity, the first side cavity, and the second side cavity by a molding material supply unit;
separating the upper mold from the bottom mold by the first loader and/or the second loader;
setting the upper cavity to a second position lower than the first position in the first direction by the first driving part;
clamping the upper mold and the bottom mold again by the first loader and/or the second loader;
supplying the molding material to an uppermost end of the molding target by the molding material supply unit; and
separating the upper mold from the bottom mold again by the first loader and/or the second loader.

18. The molding method of claim 17, wherein the first driving part includes a first sliding block configured to move in a second direction, a first motor connected to the first sliding block and configured to drive the first sliding block in the second direction, and a first cylinder connected to the first sliding block and movably mounted in the first direction in accordance with movement of the first sliding block in the second direction.

19. The molding method of claim 17, wherein the upper mold includes a second driving part connected to the first side cavity and configured to move the first side cavity in a second direction.

20. The molding method of claim 19, wherein the second driving part is operated by a wedge mechanism.
